(19) United States
(12) Patent Application Publication
(10) Pub. No.: US 2002/0036313 A1
(43) Pub. Date: Mar. 28, 2002

(54) Memory cell capacitor structure and method of formation

(76) Inventors: Sam Yang, Boise, ID (US); Dan Gealy, Kuna, ID (US)

Correspondence Address: DICKSTEIN SHAPIRO MORIN & OSHINSKY LLP, 2101 L STREET NW, WASHINGTON, DC, 20037-1526, US

(21) Appl. No.: 10/002,176

(22) Filed: Dec. 5, 2001

Related U.S. Application Data
(62) Division of application No. 09/588,008, filed on Jun. 6, 2000.

(51) Int. Cl. H01L 31/119; H01L 29/94; H01L 29/76; H01L 27/108

(52) U.S. Cl. 257/306

(57) ABSTRACT

An improved dynamic random access memory (DRAM) device with a capacitor having reduced current leakage from the dielectric layer, and materials and methods for fabricating the improved DRAM device are disclosed. The capacitor is formed using an oxygen anneal after a top conducting layer of the capacitor is formed.

### BACKGROUND OF THE INVENTION

The present invention relates to the design and manufacture of dynamic random access memory (DRAM) devices and particularly to a method of fabrication and resulting structure of Metal-Insulator-Metal (MIM) capacitors which have reduced capacitor current leakage.

### DESCRIPTION OF RELATED ART

The memory cells of modern dynamic random access memory (DRAM) devices contain two main components: a field effect transistor and a capacitor. High memory capacity DRAM cells typically employ a non-planar capacitor structure. Two basic non-planar capacitor structures are currently popular: the trench capacitor and the stacked capacitor. Their fabrication typically require considerably more masking, deposition and etching steps than for planar capacitor structures. The MIM structure can be used for either type of non-planar capacitor. Most manufacturers of 4-megabit or larger DRAMS utilize a non-planar capacitor. A non-planar capacitor structure with a Metal-Insulator-Metal (MIM) structure provides higher capacitance and hence makes it possible to produce higher density memories.

The top and bottom conducting layers, also referred to as electrodes or plates, of a MIM capacitor are typically patterned from individual layers of various metal materials and sandwich a dielectric layer. Both the top and bottom conducting layers are often made with the same material; however this is not a requirement. Increasing the dielectric constant for the dielectric layer allows greater charge to be stored in a cell capacitor for a given dielectric thickness. To this end Tantalum Oxide and Barium Strontium Titanate (BST) have been described as useful dielectric materials, as they both have high dielectric constants, also referred to as high permittivity or large capacitance. See, U.S. Pat. No. 5,142,438; Benjamin Chih-ming Lai and Joseph Ya-min Lee, Leakage Current Mechanism of Metal-Ta₂O₅-Metal Capacitors for Memory Device Applications, 146 Journal of the Electrochemical Society 262 (1999); Tomonori Aoyama, Soichi Yamazaki, and Keitaro Imai, Ultrathin Ta₂O₅ Film Capacitor with Ru Bottom Electrode, 145 Journal of the Electrochemical Society 2961 (1998); and G. W. Dietz, M. Schumacher, R Waser, S. K. Streifffer, C. Basceri, and A. I. Kingon, Leakage Currents in Ba_{0.7}Sr_{0.3}TiO₃ Thin Films for Ultra-density Dynamic Random Access Memories, 82 Journal of Applied Physics 2359 (1997). The higher the permittivity or dielectric capacitance of the dielectric material, the more charge can be stored by the capacitor. In addition a smaller capacitor with a higher permittivity can also store the same amount of charge as a larger capacitor with a lower permittivity.

As discussed in cited materials, when a Tantalum Oxide or BST film is used as a dielectric layer in a stacked capacitor structure an oxygen annealing process must be employed after dielectric film deposition to reduce the high current leakage. As formed the dielectric layer contains defects such as oxygen vacancies. The oxygen anneal performed before depositing the top conducting layer fills oxygen vacancies in the dielectric layer. The cited references teach that current leakage from a MIM stacked capacitor is significantly reduced after an oxygen anneal is performed on the dielectric layer. However, during subsequent wafer fabrication, the dielectric layer develops oxygen vacancies which contribute to capacitor current leakage. For example a Tantalum Oxide film could react with Chlorine or Fluorine ions used during a dry etch, especially if the etch is formed at temperatures greater than 200 degrees Celsius.

What is needed is a DRAM cell which further reduces the current leakage from a capacitor.

### SUMMARY OF THE INVENTION

The present invention is directed to an improved capacitor for a semiconductor device, especially a MIM Dynamic Random Access Memory (DRAM) device, which has a reduced current leakage. The invention also relates to a method of fabricating a capacitor, e.g., a MIM capacitor, having reduced current leakage. The capacitor is constructed with a bottom and top conducting layer sandwiching a dielectric layer. The bottom conducting layer could be a metal, metal alloy, conducting metal oxide, or metal nitride. It is preferred that it is not permeable to oxygen. The top conducting layer is a member of the noble metal group or is a conducting metal oxide, and should be permeable to oxygen. The dielectric layer is a dielectric metal oxide with a dielectric constant between 7 and 300 and may, for example, be a Tantalum Oxide or BST film.

The method of the invention includes the following steps. The bottom conducting layer is deposited and patterned then the dielectric layer is deposited over the bottom conducting layer. An anneal is performed on the exposed dielectric layer surface with an oxidizing compound gas. The top conducting layer is then deposited over the dielectric layer. The method of the invention improves the capacitor's charge retention through the use of an oxidizing compound gas anneal after the top conducting layer is formed. The oxygen ions pass through the oxygen permeable top conducting layer and are diffused into the dielectric layer and fill oxygen vacancies created in the dielectric layer during the deposition and patterning of the top conducting layer which reduces current leakage through the dielectric layer.

The second anneal may be performed for a period of between 10 seconds and 60 minutes at a temperature of between 300 and 800 degrees Celsius and at a pressure of 1 to 760 torr. Also disclosed are preferred compounds for use as the top and bottom conducting layers of the stacked capacitor and for use in the anneal step. The anneal step can also be enhanced with plasma, remote plasma, or ultraviolet light.

### BRIEF DESCRIPTION OF THE DRAWINGS

These and other advantages and features of the invention will be more readily understood from the following detailed description of the invention which is provided in connection with the accompanying drawings.

FIG. 1 is a cross-sectional view of a stacked capacitor of a dynamic random access memory (DRAM) array which is fabricated in accordance with the invention.

FIG. 2 is a graphical comparison of the current leakage of a stacked capacitor with a top conducting layer of Platinum (Pt), a bottom conducting layer of Tungsten Nitride (WNₓ), a dielectric layer of Tantalum Pentoxide (Ta₂O₅) before and after a second anneal step performed on the top conducting layer.

FIG. 3 is a graphical comparison of the current leakage of four stacked capacitors with a top and bottom conducting layer of Platinum (Pt) and a dielectric layer of Barium Strontium Titanate (BST) after several different anneal steps were performed on the four capacitors.

FIG. 4 illustrates a processor based system employing an improved dynamic random access memory (DRAM) device with a capacitor fabricated in accordance with the present invention.

### DESCRIPTION OF THE PREFERRED EMBODIMENTS

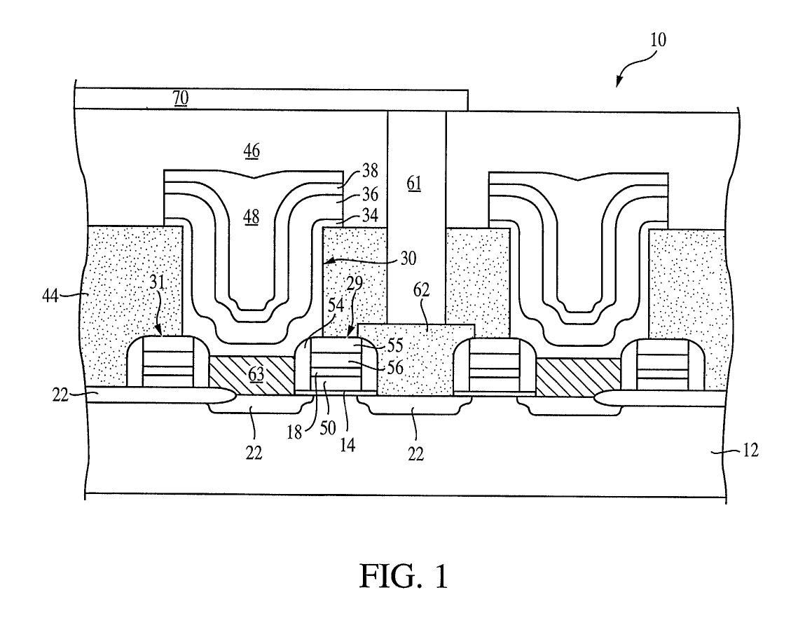

Referring now to FIG. 1, a cross-sectional portion of a dynamic random access memory (DRAM) array 10 of a stacked capacitor design is depicted after a final insulating layer 48 is applied to the capacitor cell. The capacitor cell is built on a substrate 12, which also contains a gate oxide region 14 and a pair of source/drain diffusion regions 22. A pair of gate stacks 29, 31 are formed by an oxide layer 50, doped poly-silicon layer 18, a silicide region 56, and an insulating cap layer 55. The doped poly-silicon layer 18 of gate stack 29 acts as a word line for the DRAM device. In this embodiment stacked gate 29 and diffusion regions 22, form an access transistor for a memory cell which includes the access transistor and a capacitor. Electrically insulated sidewall spacers 54 are formed on the sidewalls of the gate stacks 29, 31. Also shown are a pair of electrically conductive plugs 62, 63 extending through to the respective diffusion regions 22. An insulating layer 44 of Borophosphosilicate glass (BPSG) or other suitable insulation material is provided over the stacked gates 29, 31 and substrate 12 and the plugs 62, 63 are formed in this insulating layer.

An overlying insulating layer 46 of BPSG or other suitable insulation material layer is provided over insulating layer 44, and includes an opening 30 through to conductive plug 63. Another opening is formed in layer 46 down to plug 62 and is filled with a conductor 61. A capacitor is formed in opening 30 and includes a bottom conducting layer 34, a dielectric layer 36, and a top conducting layer 38. After the bottom conducting layer 34 and dielectric layer 36 are deposited a first anneal is performed on the capacitor prior to depositing the top conducting layer 38.

The dielectric layer 36 anneal is performed with an oxidizing gas, for between 10 seconds and 60 minutes, preferably between 10 seconds to 30 minutes, at a temperature of between 300 and 800 degrees Celsius, preferably between 400 and 650 degrees Celsius, and at a pressure of between 1 to 760 torr, preferably 2 to 660 torr. Suitable oxidizing gas compounds for use in the anneal step include: Oxygen (O₂), Ozone (O₃), Nitrous Oxide (N₂O), Nitric Oxide (NO), and water vapor (H₂O). These gases can be introduced individually into an oxidizing chamber or can be produced from reactions of other materials in the oxidization chamber. The oxidizing gas could also be a mixture of one or more these gases with an inert gas such as Argon (Ar), Helium (He), Nitrogen (N₂), or other compound mixtures which produces reacting oxygen ions. The introduction of these materials during the dielectric anneal may also be enhanced by plasma, remote plasma, or ultraviolet light. The flow rate of the gas should be between 0.01 and 10 liters per minute (1/min). A typical prior art process for the dielectric anneal on a dielectric layer of Tantalum Oxide is Ozone gas for 3 minutes, at a temperature of 475 degrees Celsius, and at a pressure of 4.0 torr. A typical prior art process for the dielectric anneal on a dielectric layer of Barium Strontium Titanate (BST) is Ozone gas, enhanced with plasma for 3 minutes at a temperature of 475 degrees Celsius at a pressure of 4.0 torr.

After the dielectric anneal, the top conducting layer 38 is deposited patterned, and etched such that capacitors are formed in opening 30 on the wafer 12. An anneal in the presence of oxygen after a dielectric layer 36 of Tantalum Oxide or BST film has been deposited replenishes much of the oxygen lost from the dielectric layer 36 during the layer's deposition.

The present invention further improves the dielectric property of the dielectric layer 36 by adding an oxidizing gas anneal (second anneal) which fills the oxygen voids created in the dielectric layer 36 after the top conducting layer 38 is deposited. The second anneal should be performed with an oxidizing gas, for between 10 seconds and 60 minutes, preferably between 10 seconds to 30 minutes, at a temperature of between 300 and 800 degrees Celsius, preferably between 400 and 750 degrees Celsius, and at a pressure of between 1 to 760 torr, preferably 2 to 660 torr. Suitable oxidizing gas compounds for use in the second anneal step include: Oxygen (O₂), Ozone (O₃), Nitrous Oxide (N₂O), Nitric Oxide (NO), and water vapor (H₂O). These gases can be introduced individually into an oxidizing chamber or can be produced from reactions of other materials in the oxidization chamber. The oxidizing gas could also be a mixture of one or more these gases with an inert gas such as Argon (Ar), Helium (He), Nitrogen (N₂), or other compound mixtures which produces reacting oxygen ions. The introduction of these materials during the second anneal may also be enhanced by plasma, remote plasma, or ultraviolet light. The flow rate of the gas is between 0.01 and 10 liters per minute (1/min).

After the capacitor cell is formed the substrate 12 is then coated with insulating layer 48 of BPSG or other suitable insulation material. Also shown in FIG. 1 is an electrically conductive bit line 70 which connects to active region 22 through conductive plugs 61 and 62 and word line 18, which is also the gate of access transistor 29. The array and peripheral circuitry are then completed using techniques well-known in the art.

A first preferred embodiment for a stacked capacitor cell has a bottom conducting layer 34 and top conducting layer 38 formed from a noble metal, which resists oxidization. The bottom conducting layer 34 can be permeable to oxygen, but it should resist oxidization. However, if the bottom layer 34 is permeable to oxygen, an oxygen barrier layer may be needed between the bottom layer 34 and plug 63 to prevent layer 63 made of poly-silicon from oxidizing during the anneal process. The bottom conducting layer 34 and top conducting layer 38 can be of different materials. The bottom conducting layer 34 can be a metal, metal alloy, conducting metal oxide, or metal nitride. The bottom conducting layer is formed of compounds selected from the group consisting of: Platinum (Pt), Platinum Rhodium (PtRh), Platinum Iridium (PtIr), Ruthenium, Ruthenium Oxide (RuO₂), Rhodium Oxide (RhO₂), Chromium Oxide (CrO₂), Molybdenum Oxide (MoO₂), Rhemium Oxide (ReO₃), Iridium Oxide (IrO₂), Titanium Oxides (TiO₁ or TiO₂), Vanadium Oxides (VO₁ or VO₂), Niobium Oxides (NbO₁ or NbO₂), and Tungsten Nitride (WNx, WN, or W₂N). The bottom conducting layer 34 is preferably formed from Platinum (Pt), a Platinum alloy, such as Platinum Rhodium (PtRh) or Platinum Iridium (PtIr), or Tungsten Nitride (WNx, WN, or W₂N).

The dielectric layer 36 should be an metal dielectric oxide with a dielectric constant between 7 and 300. The dielectric layer 36 is formed from compounds selected from the group consisting of: Tantalum Oxide, Tantalum Pentoxide (Ta₂O₅), Barium Strontium Titanate (BST), Aluminum Oxide (Al₂O₃), Zirconium Oxide (ZrO₂), Praseodymium Oxide (PrO₂), Tungsten Oxide (WO₃), Niobium Pentoxide (Nb₂O₅), Strontium Bismuth Tantalate (SBT), Hafnium Oxide (HfO₂), Hafnium Silicate, Lanthanum Oxide (La₂O₃), Yttrium Oxide (Y₂O₃) and Zirconium Silicate. The dielectric layer 36 is preferably formed from Tantalum Pentoxide (Ta₂O₅), Barium Strontium Titanate (BST), Strontium Bismuth Tantalate (SBT), Aluminum Oxide (Al₂O₃), Zirconium Oxide (ZrO₂) or Hafnium Oxide (HfO₂). If the dielectric layer 36, is Tantalum Oxide, it could be amorphous or crystalline. If it is amorphous, it could be crystallized during the annealing process to achieve a higher dielectric permittivity. For example Tantalum Oxide amorphous has a dielectric constant between 18 and 25; however crystalline Tantalum Oxide has a dielectric constant 40. Prior to depositing the top conducting layer 38, the first anneal described above is performed.

The top conducting layer 38 must be a non-oxidizing metal, a noble metal, or a conducting metal oxide permeable to oxygen to allow oxidizing gas used in the second anneal step after the top conducting layer 38 is patterned to pass through the top conducting layer 38 and into the dielectric layer 36. The top conducting layer 38 is formed of compounds selected from the group consisting of: Platinum (Pt), Platinum Rhodium (PtRh) or Platinum Iridium (PtIr), Ruthenium, Ruthenium Oxide (RuO₂), Rhodium Oxide (RhO₂), Chromium Oxide (CrO₂), Molybdenum Oxide (MoO₂), Rhemium Oxide (ReO₃), Iridium Oxide (IrO₂), Titanium Oxides (TiO₁ or TiO₂), Vanadium Oxides (VO₁ or VO₂), and Niobium Oxides (NbO₁ or NbO₂). The top conducting layer 38 is preferably formed from Platinum (Pt) or a Platinum alloy, such as Platinum Rhodium (PtRh) or Platinum Iridium (PtIr).

A second preferred embodiment for a stacked capacitor cell has a bottom 34 and top 38 conducting layer formed of a compound selected from the group consisting of: Platinum, Platinum Rhodium (PtRh), or Platinum Iridium (PtIr) and a dielectric layer 36 formed of a layer of either Tantalum Oxide or Barium Strontium Titanate (BST).

A third preferred embodiment of a stacked capacitor cell has a bottom conducting layer 34 formed of Tungsten Nitride (WNx, WN, or W₂N), a dielectric layer 36 formed of Aluminum Oxide (Al₂O₃), and a top conducting layer 38 formed of a compound selected from the group consisting of: Platinum, Platinum Rhodium (PtRh), or Platinum Iridium (PtIr).

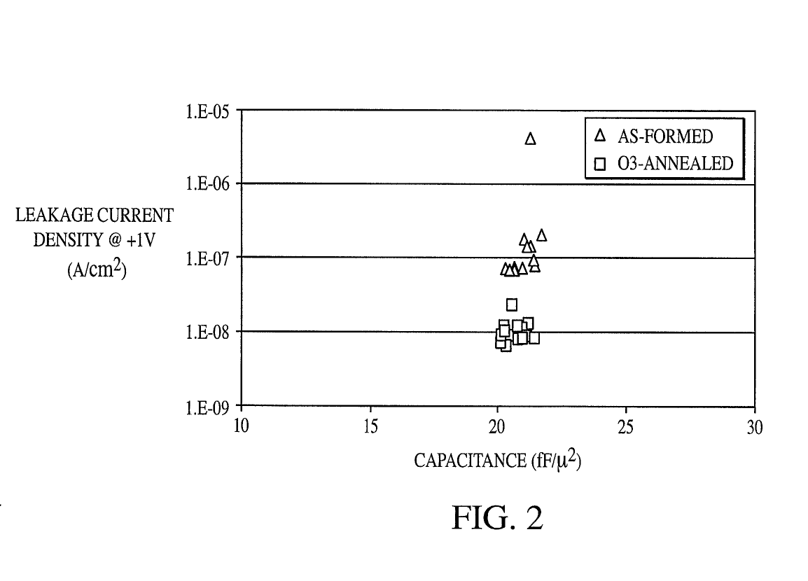

FIG. 2 is a comparison of the current leakage of a stacked capacitor with a Platinum (Pt) top conducting layer 38 and a Tungsten Nitride (WNₓ) bottom conducting layer 34 and a Tantalum Pentoxide (Ta₂O₅) dielectric layer 36 before and after the top conducting layer 38 is annealed. The samples were constructed with a prior art first anneal on the dielectric layer 36 of Ozone gas, enhanced with plasma for 3 minutes at a temperature of 475 degrees Celsius at a pressure of 4.0 torr. After depositing the top conducting layer 38, a second oxidizing gas anneal, in accordance with the present invention, was performed for 3 minutes at a temperature of 475 degrees Celsius at a pressure of 4 torr, with an oxygen and ozone mixture. The capacitance of the capacitor, biased at 1 volt, was then measured after it had cooled to a temperature of 85 degrees Celsius. The x-axis shows the capacitance in capacitance per units/area (femto-Farad per micrometer squared (fF/μ²)). The y-axis shows the leakage current density in current per area (amperes per centimeter squared (A/cm²)). As the diagram shows the capacitance of the capacitor before and after the anneal was approximately 21 (fF/μ²); however the current leakage density after the anneal was reduced by a factor of approximately 10.

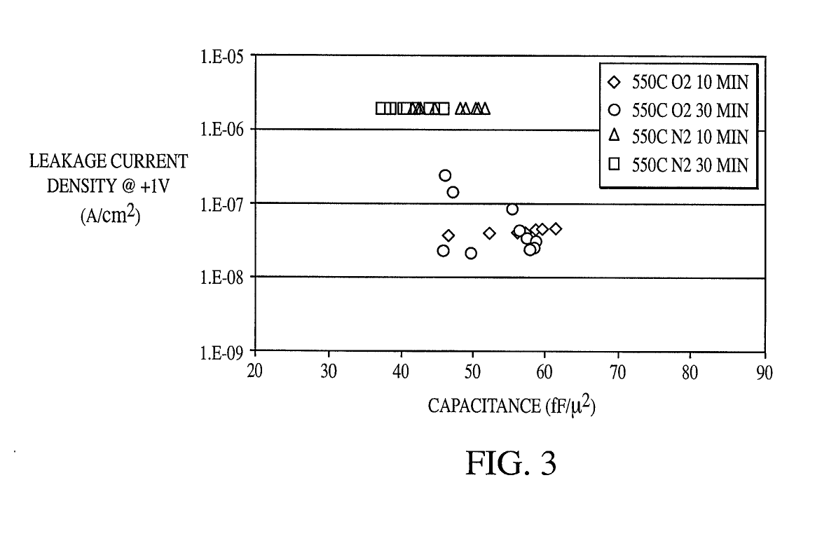

FIG. 3 is a comparison of the current leakage between a stacked capacitor with a Platinum (Pt) top 38 and bottom 34 conducting layer and a Barium Strontium Titanate (BST) dielectric layer. The four samples were each constructed with a prior art first anneal on the dielectric layer 36 of Ozone gas, enhanced with plasma for 3 minutes at a temperature of 475 degrees Celsius at a pressure of 4.0 torr. A second anneal step, in accordance with the present invention, was performed on four samples after the top conducting layer 38 was deposited, at a temperature of 550 degrees Celsius and a pressure of 660 torr. One capacitor was subject to Oxygen gas anneals of 10 minutes, one capacitor was subject to Oxygen gas anneals for 30 minutes, and one with Nitrogen gas for 10 minutes and one with Nitrogen gas for 30 minutes. The capacitance of the capacitors, biased at 1 volt, was then measured after anneal. The wafer was heated to 85° C. during measurement to simulate stringent real DRAM application conditions.

The x-axis shows the capacitance in capacitance per unit area (femto-Farad per micrometer squared (fF/μ²)). The y-axis shows the leakage current density in current per unit area (amperes per centimeter squared (A/cm ²)). As the diagram shows the current leakage density for capacitors annealed with Nitrogen gas for both the 10 and 30 minute anneals produced a current leakage that exceed 2000 (A/cm²), which was the maximum level the machine could detect. As expected, the capacitors annealed with Nitrogen gas, which is an inert non-oxidizing gas, produced no current leakage reduction. However, the two capacitors which were annealed with Oxygen gas for 10 and 30 minute anneals had current leakage density reductions by a factor of 10 to 100 times of the Nitrogen gas samples. Thus the test shows that performing an anneal step with an oxidizing gas after the top conducting layer 38 is formed substantially reduced capacitor current leakage.

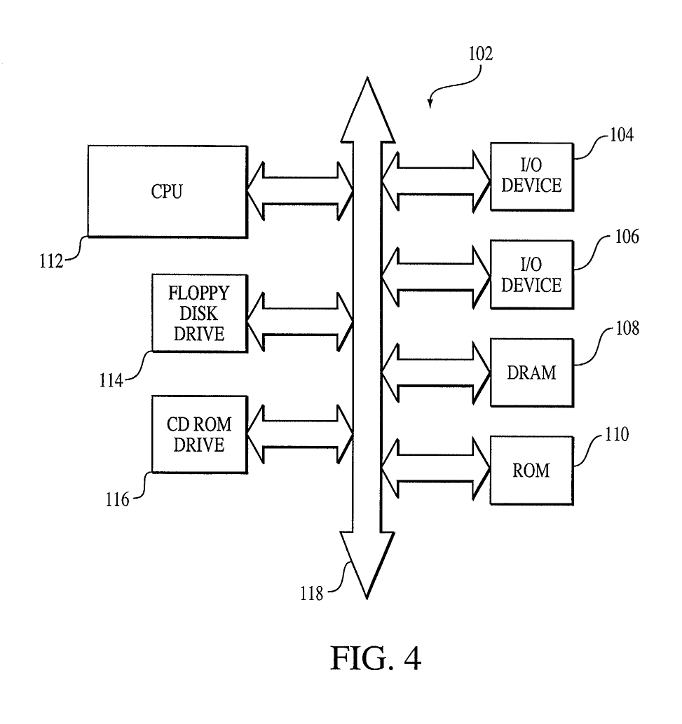

FIG. 4 illustrates a typical processor based system 102, including a DRAM memory device 108 containing a stacked capacitor fabricated according to the present invention as illustrated in FIG. 1 and described above. A processor based system, such as a computer system 102, generally comprises a central processing unit (CPU) 112, for example a microprocessor, that communicates with one or more input/output(I/O) devices 104, 106 over a bus 118. The computer system 102 also includes a read only memory device (ROM) 110 and may include peripheral devices such as floppy disk drive 114 and a CD ROM drive 116 which also communicates with the CPU 112 over the bus 118. DRAM device 108 preferably has a stacked capacitor which includes a top conducting layer anneal as previously described with reference to FIGS. 1-3.

While the invention has been illustrated and described in detail in the drawings and foregoing description, the above description and accompanying drawings are only illustrative of preferred embodiment which can achieve the features and advantages of the present invention. It is not intended that the invention be limited to the embodiments shown and described in detail herein. The invention is only limited by the scope of the following claims.

What is claimed as new and desired to be protected by Letters Patent of the United States is:

1. A capacitor for a semiconductor device, said capacitor comprising:
a bottom conducting layer;
a dielectric layer deposited on said bottom conducting layer; and
an oxygen permeable top conducting layer deposited and annealed on said dielectric layer.

2. The capacitor of claim 1, wherein said bottom conducting layer is formed of a material selected from the noble metal group.

3. The capacitor of claim 1, wherein said bottom conducting layer is formed of a metal.

4. The capacitor of claim 1, wherein said bottom conducting layer is formed of a metal alloy.

5. The capacitor of claim 1, wherein said bottom conducting layer is formed of a conducting metal oxide.

6. The capacitor of claim 1, wherein said bottom conducting layer is formed of a metal nitride.

7. The capacitor of claim 1, wherein said bottom conducting layer is formed of a material selected from the group consisting of: Platinum (Pt), Platinum Rhodium (PtRh), Platinum Iridium (PtIr), Ruthenium, Ruthenium Oxide (RuQ₂), Rhodium Oxide (RhO₂), Chromium Oxide (CrO₂), Molybdenum Oxide (MoO₂), Rhemium Oxide (ReO₃), Iridium Oxide (IrO₂), Titanium Oxides (TiO₁ or TiO₂), Vanadium Oxides (VO₁ or VO₂), Niobium Oxides (NbO₁ or NbO₂), and Tungsten Nitride (WNx, WN, or W₂N).

8. The capacitor of claim 7, wherein said bottom conducting layer is formed of a material selected from the group consisting of: Platinum (Pt), Platinum Rhodium (PtRh), Platinum Iridium (PtIr), and Tungsten Nitride (WNx, WN, or W₂N).

9. The capacitor of claim 1, wherein said bottom conducting layer is placed on top of an oxygen barrier.

10. The capacitor of claim 1, wherein said dielectric layer is a dielectric metal oxide layer.

11. The capacitor of claim 1, wherein said dielectric layer has a dielectric constant between 7 and 300.

12. The capacitor of claim 1, wherein said dielectric layer is formed of a material selected from the group consisting of: Tantalum Oxide, Tantalum Pentoxide (Ta₂O₅), Barium Strontium Titanate (BST), Aluminum Oxide (Al₂O₃), Zirconium Oxide (ZrO₂), Praseodymium Oxide (PrO₂), Tungsten Oxide (WO₃), Niobium Pentoxide (Nb₂O₅), Strontium Bismuth Tantalate (BST), Hafnium Oxide (HfO₂), Hafnium Silicate, Lanthanum Oxide (La₂O₃), Yttrium Oxide (Y₂O₃) and Zirconium Silicate.

13. The capacitor of claim 12, wherein said dielectric layer is formed of a material selected from the group consisting of: Tantalum Oxide, Tantalum Pentoxide (Ta₂O₅), Barium Strontium Titanate (BST), Strontium Bismuth Tantalate (SBT), Aluminum Oxide (Al₂O₃), Zirconium Oxide (ZrO₂) and Hafnium Oxide (HfO₂).

14. The capacitor of claim 13, wherein said dielectric layer is Tantalum Oxide and is amorphous or crystalline.

15. The capacitor of claim 1, wherein said top conducting layer is formed of a material selected from the noble metal group.

16. The capacitor of claim 1, wherein said top conducting layer is formed of a non-oxidizing metal permeable to oxygen.

17. The capacitor of claim 1, wherein said top conducting layer is formed of a conducting metal oxide.

18. The capacitor of claim 1, wherein said top conducting layer is formed of a material selected from the group consisting of: Platinum (Pt), Platinum Rhodium (PtRh), Platinum Iridium (PtIr), Ruthenium, Ruthenium Oxide (RuO₂), Rhodium Oxide (RhO₂), Chromium Oxide (CrO₂), Molybdenum Oxide (MoO₂), Rhemium Oxide (ReO₃), Iridium Oxide (IrO₂), Titanium Oxides (TiO₁ or TiO₂), Vanadium Oxides (VO₁ or VO₂), and Niobium Oxides (NbO₁ or NbO₂).

19. The capacitor of claim 18, wherein said top conducting layer is formed of a material selected from the group consisting of: Platinum (Pt), Platinum Rhodium (PtRh), and Platinum Iridium (PtIr).

20. The capacitor of claim 1, wherein said bottom and top conducting layers are formed of a material selected from the group consisting of: Platinum, Platinum Rhodium (PtRh), or Platinum Iridium (PtIr) and said dielectric layer is a layer of Tantalum Oxide.

21. The capacitor of claim 1, wherein said bottom and top conducting layers are formed of a material selected from the group consisting of: Platinum, Platinum Rhodium (PtRh), or Platinum Iridium (PtIr) and said dielectric layer is a layer of Barium Strontium Titanate (BST).

22. The capacitor of claim 1, wherein said top conducting layer is formed of a material selected from the group consisting of: Platinum, Platinum Rhodium (PtRh), or Platinum Iridium (PtIr) and said bottom conducting layer is a layer of Tungsten Nitride (WNx, WN, or W₂N) layer and said dielectric layer is a layer of Aluminum Oxide (Al₂O₃).

23. The capacitor of claim 1, wherein said top conducting layer is annealed with an oxygen compound.

24. The capacitor of claim 23, wherein said oxygen annealed layer is one annealed in the presence of a material selected from the group consisting of: Oxygen (O₂), Ozone (O₃), Nitrous Oxide (N₂O), Nitric Oxide (NO), and water vapor (H₂O).

25. The capacitor of claim 23, wherein said oxygen annealed layer is one annealed in the presence of a gas mixture containing at least one element selected from the group consisting: Oxygen (O₂), Ozone (O₃), Nitrous Oxide (N₂O), Nitric Oxide (NO), and water vapor (H₂O).

26. The capacitor of claim 23, wherein oxygen annealed layer is a plasma enhanced annealed layer.

27. The capacitor of claim 26, wherein said oxygen containing anneal is a remote plasma enhanced anneal.

28. The capacitor of claim 23, wherein said oxygen containing anneal is an ultraviolet light enhanced anneal.

29. The capacitor of claim 1, wherein said capacitor is a stacked capacitor.

30. The capacitor of claim 1, wherein further comprising an access transistor connected to said capacitor.

31. The capacitor of claim 1, wherein said capacitor forms part of a dynamic random access memory cell.

32. A method of forming a capacitor in a semiconductor device, said method comprising:
forming a bottom conducting layer;
forming a dielectric layer over the bottom conducting layer;
forming a top conducting layer over the dielectric layer; and
annealing the top conducting layer after it is formed.

33. A method of forming a capacitor of claim 32, wherein said capacitor is formed over a conductive plug, said method further comprising depositing an oxygen barrier over said conductive plug prior to forming the bottom conducting layer.

34. A method of forming a capacitor of claim 32, said method further comprising:
annealing the dielectric layer after it is formed.

35. A method of forming a capacitor of claim 32, wherein said bottom conducting layer is formed of a material selected from the noble metal group.

36. A method of forming a capacitor of claim 32, wherein said bottom conducting layer is formed of a metal.

37. A method of forming a capacitor of claim 32, wherein said bottom conducting layer is formed of a metal alloy.

38. A method of forming a capacitor of claim 32, wherein said bottom conducting layer is formed of a conducting metal oxide.

39. A method of forming a capacitor of claim 32, wherein said bottom conducting layer is formed of a metal nitride.

40. A method of forming a capacitor of claim 32, wherein said bottom conducting layer is formed of a material selected from the group consisting of: Platinum (Pt), Platinum Rhodium (PtRh), Platinum Iridium (PtIr), Ruthenium, Ruthenium Oxide (RuO₂), Rhodium Oxide (RhO₂), Chromium Oxide (CrO₂), Molybdenum Oxide (MoO₂), Rhemium Oxide (ReO₃), Iridium Oxide (IrO₂), Titanium Oxides (TiO₁ or TiO₂), Vanadium Oxides (VO₁ or VO₂), Niobium Oxides (NoO₁ or NbO₂), and Tungsten Nitride (WNx, WN or W₂N).

41. A method of forming a capacitor of claim 40, wherein said bottom conducting layer is formed of a material selected from the group consisting of: Platinum (Pt), Platinum Rhodium (PtRh), Platinum Iridium (PtIr), and Tungsten Nitride (WNx, WN or W₂N).

42. A method of forming a capacitor of claim 32, wherein said dielectric layer is a dielectric metal oxide layer.

43. A method of forming a capacitor of claim 32, wherein said dielectric layer has a dielectric constant between 7 and 300.

44. A method of forming a capacitor of claim 32, wherein said dielectric layer is formed of a material selected from the group consisting of: Tantalum Oxide, Tantalum Pentoxide (Ta₂O₅), Barium Strontium Titanate (BST), Aluminum Oxide (Al₂O₃), Zirconium Oxide (ZrO₂), Praseodymium Oxide (PrO₂), Tungsten Oxide (W0₃), Niobium Pentoxide (Nb₂O₅), Strontium Bismuth Tantalate (SBT), Hafnium Oxide (HfO₂), Hafnium Silicate, Lanthanum Oxide (La₂O₃), Yttrium Oxide (Y₂O₃), and Zirconium Silicate.

45. A method of forming a capacitor of claim 44, wherein said dielectric layer is formed of a material selected from the group consisting of: Tantalum Oxide, Tantalum Pentoxide (Ta₂O₅), Barium Strontium Titanate (BST), Strontium Bismuth Tantalate (BST), Aluminum Oxide (Al₂O₃), Zirconium Oxide (ZrO₂) and Hafnium Oxide (HfO₂).

46. A method of forming a capacitor of claim 45, wherein said dielectric layer is Tantalum Oxide and is crystalline or amorphous material.

47. A method of forming a capacitor of claim 46, wherein said amorphous dielectric layer is heated to a temperature above 200 degrees Celsius to change said dielectric layer from an amorphous material to a crystalline material.

48. A method of forming a capacitor of claim 32, wherein said top conducting layer is formed of a material selected from the noble metal group.

49. A method of forming a capacitor of claim 32, wherein said top conducting layer is formed of a non-oxidizing metal permeable to oxygen.

50. A method of forming a capacitor of claim 32, wherein said top conducting layer is formed of a conducting metal oxide.

51. A method of forming a capacitor of claim 32, wherein said top conducting layer is formed of a material selected from the group consisting of. Platinum (Pt), Platinum Rhodium (PtRh), Platinum Iridium (PtIr), Ruthenium, Ruthenium Oxide (RuO₂), Rhodium Oxide (RhO₂), Chromium Oxide (CrO₂), Molybdenum Oxide (MoO₂), Rhemium Oxide (ReO₃), Iridium Oxide (IrO₂), Titanium Oxides (TiO₁ or TiO₂), Vanadium Oxides (VO₁ or VO₂), and Niobium Oxides (NbO₁ or NbO₂).

52. A method of forming a capacitor of claim 51, wherein said top conducting layer is formed of a material selected from the group consisting of: Platinum (Pt), Platinum Rhodium (PtRh), and Platinum Iridium (PtIr).

53. A method of forming a capacitor of claim 32, wherein said bottom and top conducting layers are formed of a material selected from the group consisting of: Platinum, Platinum Rhodium (PtRh), or Platinum Iridium (PtIr) and said dielectric layer is a layer of Tantalum Oxide.

54. A method of forming a capacitor of claim 32, wherein said bottom and top conducting layers are formed of a material selected from the group consisting of: Platinum, Platinum Rhodium (PtRh), or Platinum Iridium (PtIr) and said dielectric layer is a layer of Barium Strontium Titanate (BST) or Strontium Bismuth Tantalate (SBT).

55. A method of forming a capacitor of claim 32, wherein said top conducting layers are formed of a material selected from the group consisting of. Platinum, Platinum Rhodium (PtRh), or Platinum Iridium (PtIr) and said bottom conducting layer is a layer of Tungsten Nitride (WNx, WN or W₂N) layer and said dielectric layer is a layer of Aluminum Oxide (Al₂O₃)

56. A method of forming a capacitor of claim 32, wherein said annealing is performed with an oxidizing gas.

57. A method of forming a capacitor of claim 56, wherein said annealing is performed with a material selected from the group consisting of. Oxygen (O₂), Ozone (O₃), Nitrous Oxide (N₂O), Nitric Oxide (NO), and water vapor (H₂O).

58. A method of forming a capacitor of claim 57, wherein said annealing is performed with a gas mixture containing at least one element selected from the group consisting: Oxygen (O₂), Ozone (O₃), Nitrous Oxide (N₂O), Nitric Oxide (NO), and water vapor (H₂O).

59. A method of forming a capacitor of claim 56, wherein said annealing is a plasma enhanced annealing.

60. A method of forming a capacitor of claim 59, wherein said annealing is a remote plasma enhanced annealing.

61. A method of forming a capacitor of claim 56, wherein said annealing is an ultraviolet light enhanced annealing.

62. A method of forming a capacitor of claim 32, wherein said annealing is performed at a temperature between 300 and 800 degrees Celsius.

63. A method of forming a capacitor of claim 62, wherein said annealing is performed at a temperature between 400 and 750 degrees Celsius.

64. A method of forming a capacitor of claim 32, wherein said annealing is performed at a pressure between 1 and 760 torr.

65. A method of forming a capacitor of claim 64, wherein said annealing is performed at a pressure between 2 and 660 torr.

66. A method of forming a capacitor of claim 32, wherein said annealing is performed for between 10 seconds and 60 minutes.

67. A method of forming a capacitor of claim 66, wherein said annealing is performed for between 10 seconds and 30 minutes.

68. A method of forming a capacitor of claim 32, wherein said annealing is performed in the presence of an oxygen as with a gas flow rate between 0.01 and 10 liters per second.

69. A processor system comprising:
a processor;
and a memory device coupled to said processor further comprising a capacitor structure,
wherein said capacitor structure comprises:
a bottom conducting layer;
a dielectric layer deposited on said bottom conducing layer; and
an oxygen permeable top conducting layer deposited and annealed on said dielectric layer.

70. A processor system of claim 69, wherein said capacitor further comprises:
an annealed dielectric layer after it is formed.

71. The system of claim 69, wherein said bottom conducting layer is formed of a material
selected from the noble metal group.

72. The system of claim 69, wherein said bottom conducting layer is formed of a metal.

73. The system of claim 69, wherein said bottom conducting layer is formed of a metal alloy.

74. The system of claim 69, wherein said bottom conducting layer is formed of a conducting metal oxide.

75. The system of claim 69, wherein said bottom conducting layer is formed of a metal nitride.

76. The system of claim 69, wherein said bottom conducting layer is formed of a material selected from the group consisting of: Platinum (Pt), Platinum Rhodium (PtRh), Platinum Iridium (PtIr), Ruthenium, Ruthenium Oxide (RuO₂), Rhodium Oxide (RhO₂), Chromium Oxide (CrO₂), Molybdenum Oxide (MoO₂), Rhemium Oxide (ReO₃), Iridium Oxide (IrO₂), Titanium Oxides (TiO₁ or TiO₂), Vanadium Oxides (VO₁ or VO₂), Niobium Oxides (NbO₁ or NbO₂), and Tungsten Nitride (WN, WNX, or W₂N).

77. The system of claim 76, wherein said bottom conducting layer is formed of a material selected from the group consisting of. Platinum (Pt), Platinum Rhodium (PtRh), and Platinum Iridium (PtIr), and Tungsten Nitride (WN, WNX, or W₂N).

78. The system of claim 69, wherein said bottom conducting layer is placed on top of an oxygen barrier.

79. The system of claim 69, wherein said dielectric layer is a dielectric metal oxide layer.

80. The system of claim 69, wherein said dielectric layer has a dielectric constant between 7 and 300.

81. The system of claim 69, wherein said dielectric layer is formed of a material selected from the group consisting of: Tantalum Oxide, Tantalum Pentoxide (Ta₂O₅), Barium Strontium Titanate (BST), Aluminum Oxide (Al₂O₃), Zirconium Oxide (ZrO₂), Praseodymium Oxide (PrO₂), Tungsten Oxide (WO₂), Niobium Pentoxide (Nb₂O₅), Strontium Bismuth Tantalate (SBT), Hafnium Oxide (HfO₂), Hafnium Silicate, Lanthanum Oxide (La₂O₃), Yttrium Oxide (Y₂O₃) and Zirconium Silicate.

82. The system of claim 81, wherein said dielectric layer is formed of a material selected from the group consisting of: Tantalum Pentoxide (Ta₂O₅), Barium Strontium Titanate (BST), Strontium Bismuth Tantalate (SBT), Aluminum Oxide (Al₂O₃), Zirconium Oxide (ZrO₂) and Hafnium Oxide (HfO₂).

83. The system of claim 69, wherein said top conducting layer is formed of a material selected from the noble metal group.

84. The system of claim 69, wherein said top conducting layer is formed of a non-oxidizing metal permeable to oxygen.

85. The system of claim 69, wherein said top conducting layer is formed of a conducting metal oxide.

86. The system of claim 69, wherein said top conducting layer is formed of a material selected from the group consisting of: Platinum (Pt), Platinum Rhodium (PtRh), Platinum Iridium (PtIr), Ruthenium, Ruthenium Oxide (RuO₂), Rhodium Oxide (RhO₂), Chromium Oxide (CrO₂), Molybdenum Oxide (MoO₂), Rhemium Oxide (ReO₃), Iridium Oxide (IrO₂), Titanium Oxides (TiO₁ or TiO₂), Vanadium Oxides (VO₁ or VO₂), and Niobium Oxides (NbO₁ or NbO₂).

87. The system of claim 86, wherein said top conducting layer is formed of a material selected from the group consisting of: Platinum (Pt), Platinum Rhodium (PtRh), and Platinum Iridium (PtIr).

88. The system of claim 69, wherein said bottom and top conducting layers are formed of a material selected from the group consisting of: Platinum, Platinum Rhodium (PtRh), or Platinum Iridium (PtIr) and said dielectric layer is a layer of Tantalum Oxide.

89. The system of claim 69, wherein said bottom and top conducting layers are formed of a material selected from the group consisting of: Platinum, Platinum Rhodium (PtRh), or Platinum Iridium (PtIr) and said dielectric layer is a layer of Barium Strontium Titanate (BST).

90. The system of claim 69, wherein said top conducting layer is formed of a material selected from the group consisting of: Platinum, Platinum Rhodium (PtRh), or Platinum Iridium (PtIr) and said bottom conducting layer is a layer of Tungsten Nitride (WNₓ, WN, or W₂N) layer and said dielectric layer is a layer of Aluminum Oxide (Al₂O₃).

91. The system of claim 69, wherein said post deposition annealed top conducting layer is annealed with an oxygen compound.

92. The system of claim 91, wherein said oxygen annealed layer is annealed in the presence of a material selected from the group consisting of: Oxygen (O₂), Ozone (O₃), Nitrous Oxide (N₂O), Nitric Oxide (NO), and a gas mixture containing Oxygen (O₂), Ozone (O₃), Nitrous Oxide (N₂O), Nitric Oxide (NO), and water vapor (H₂O).

93. The system of claim 91, wherein said oxygen annealed layer is annealed in the presence of a gas mixture containing at least one element selected from the group consisting of: Oxygen (O₂), Ozone (O₃), Nitrous Oxide (N₂O), Nitric Oxide (NO), and water vapor (H₂O)

94. The system of claim 91, wherein said oxygen annealed layer is a plasma enhanced anneal layer.

95. The system of claim 94, wherein said oxygen containing anneal is a remote plasma enhanced anneal.

96. The system of claim 91, wherein said oxygen containing anneal is an ultraviolet light enhanced anneal.
